(19) United States
(12) Patent Application Publication
(10) Pub. No.: US 2011/0052790 A1
(43) Pub. Date: Mar. 3, 2011

(54) KITS FOR AND METHODS OF REPAIR, MAINTENANCE AND SUBSTANTIAL COLOR MATCH OF CEMENTITIOUS MATERIALS

(76) Inventor: Kap Young, Oxnard, CA (US)

(21) Appl. No.: 12/548,237

(22) Filed: Aug. 26, 2009

(51) Int. Cl. C23C 16/52; B32B 43/00; C04B 14/00

(52) U.S. Cl. 427/8; 427/140; 106/712

(57) ABSTRACT

Kits for and methods of repair, maintenance and substantial color-match of existing cementitious materials are disclosed. A kit for repair, maintenance and substantial color-match includes a plurality of materials including: a plurality of cementitious powders for preparing a base cementitious mixture comparable to a base of the existing material either for substantially matching a user-selected color of, repairing the existing material or both; a plurality of pigment oxides for refining the base mixture into a refined pigmented cementitious mixture having color attributes which substantially match the color attributes of the user-selected color; a quick-setting mortar repair caulk for repairing large cracks in the existing material; a urethane sealant for repairing voids in the existing material; and a catalyzed cementitious powder for preparing a catalyzed cementitious mixture for repairing voids in the existing material. The kit for repair, maintenance and substantial color-match also includes a plurality of implements including: a plurality of applying and removing means for applying and removing either the materials, mixtures or both; a plurality of containing means for containing either the materials, mixtures or both; a plurality of measuring means for measuring the materials; and a plurality of accessories.

### BACKGROUND

1. Field of the Technology

The present application relates generally to stucco and other cementitious materials, and more particularly to kits for and methods of repair, maintenance and substantial color-match of those materials.

2. Description of the Related Art

Portland cementitious plaster, or stucco, is widely used all over the world as an exterior cladding because of its aesthetic appeal, durability, fire resistance, design flexibility, low cost and ease of maintenance.

Cracks and voids in stucco may vary considerably in width or gap of opening. Frequently the cause of the cracks and voids may determine whether they are hair-line or are wider in gap, which dictate suggested remedial treatment. In each case the crack or void must be properly cleaned. Industry practice for small cracks (cracks which the user cannot insert a dime) is to brush with an acrylic bonding resin then thinly apply a patching material while large cracks and voids should be filled with paste. When repairing large cracks and voids industry practice is to brush with an acrylic bonding resin then apply a blended filler material to a level at above the level of adjacent plaster. Significant time for such large crack and void repairs should be anticipated because the filler will likely shrink below the level of adjacent plaster, upon which another application is necessary. Further filler material likely will not match the color of the existing cementitious material.

Color non-uniformity in stucco and other cementitious material often results from: unfavorable weather conditions—fog, rain, low temperature or other adverse drying conditions—existing during application; dirt washed from roofs; soil clinging to and staining the base of walls at and above the weep screed; darkening of pigment oxides from the passage of time; non-removable efflorescence; and repair of the existing material. Industry practice is to spray fog coat evenly over the entire surface of the existing material to achieve uniform and attractive color. Indeed no method of substantially matching a user-selected color of an existing cementitious material exists.

Fog coat, produced by stucco manufacturers, is composed of fine portland cement powder, mineral pigments and other ingredients, like acrylic bonders or lime, but lacks the aggregate, like sand, perlite, etc. found in stucco. Fog coating is the application, by sprayer or brush, of a thin, very fluid mixture of water and fog coat of similar color as the existing material. Fog coat conforms to the finish of trowel-applied existing material.

Spray application of fog coat requires a thin consistency—that of milk—which often results in inadequate coverage and hiding capability. Industry practice dictates that fog coat must be prepared below 20 wt. % cement powder to water to spray apply. This thin consistency allows application via a sprayer but necessitates that at least two thin coats be applied, allowing sufficient drying time between applications.

Industry practice for stucco maintenance and repair is limited and inefficient. Results of accepted crack and void repair in existing stucco are cosmetically obvious. Fog coat must be applied over an entire existing stucco surface to deal with color non-uniformity as there are no viable methods of color matching the existing stucco. Furthermore fog coat must be prepared below 20 wt. % cement powder to water—a milky consistency—to apply via a sprayer. Thus two spray applications of fog coat are needed for sufficient coverage.

Accordingly, what are needed are kits for and methods of repair, maintenance and substantial color-match of existing stucco which overcome the deficiencies of the prior art.

### SUMMARY

Kits for and methods of repair, maintenance and substantial color-match of existing cementitious materials are disclosed. A kit for repair, maintenance and substantial color-match of existing cementitious material includes a plurality of materials including: a plurality of cementitious powders for preparing a base cementitious mixture comparable to a base of the existing material either for substantially matching a user-selected color of or for repairing the existing material; a plurality of pigment oxides for refining the base mixture into a refined pigmented cementitious mixture having color attributes which substantially match the color attributes of the user-selected color; a quick-setting mortar repair caulk for repairing large cracks in the existing material; a urethane sealant for repairing voids in the existing material; and a catalyzed cementitious powder for preparing a catalyzed cementitious mixture for repairing voids in the existing material. The kit for repair, maintenance and substantial color-match also includes a plurality of implements including: a plurality of applying and removing means for applying and removing either the materials, mixtures or both; a plurality of containing means for containing either the materials, mixtures or both; a plurality of measuring means for measuring the materials; and a plurality of accessories.

A kit for substantial color-match of a user-selected color of an existing cementitious material includes a plurality of materials including: a plurality of cementitious powders for preparing a base cementitious mixture comparable to a base of the existing material; and a plurality of pigment oxides for refining the base mixture into a refined pigmented cementitious mixture having color attributes which substantially match the color attributes of the user-selected color. The kit for substantial color-match of the user-selected color of the existing material also includes a plurality of implements including: a plurality of applying and removing means for applying and removing the mixtures; a plurality of containing means for containing either the materials, mixtures or both; a plurality of measuring means for measuring the materials; and a plurality of accessories.

A method of repair, maintenance and substantial color-match of existing cementitious material includes: determining whether a repair is needed to the existing material: if so, performing a step of determining a type of repair needed to the existing material; if not, performing a step of substantially matching a user-selected color of the existing material; determining the type of repair needed to the existing material including: if the repair is a small crack: applying a cementitious mixture in the small crack; allowing the base mixture to partially set; removing excess base mixture on the existing material around the small crack; if the repair is a large crack: applying a quick-setting mortar repair caulk in the large crack; rubbing the caulk into the large crack; removing excess caulk around and protruding from the large crack, so that the caulk is flush with a surface of the existing material; if the repair is a void: applying a urethane sealant to an interior surface of the void; applying a catalyzed cementitious mixture over the sealant so that excess catalyzed mixture protrudes from a surface of the existing material; allowing the catalyzed mixture to partially set; removing the excess catalyzed mixture around and protruding from the void, so that the catalyzed mixture is flush with the surface of the existing material; substantially matching a user-selected color of the existing material including: preparing a pigmented cementitious mixture having a hue similar to the user-selected color; refining color attributes of the pigmented mixture to substantially match the color attributes of the user-selected color; confirming that the color attributes of the refined pigmented mixture substantially match the color attributes of the user-selected color; applying, via a sprayer, the refined mixture including: tuning the sprayer for user-selected refined mixture discharge characteristics; and selectively spraying the refined mixture over part of the existing material.

A method of repairing existing cementitious material includes: determining a type of repair needed to the existing material: if the repair needed is a small crack: applying a cementitious mixture in the small crack; allowing the base mixture to partially set; removing excess base mixture on the existing material around the small crack; if the repair needed is a large crack: applying a quick-setting mortar repair caulk in the large crack; rubbing the caulk into the large crack; removing excess caulk around and protruding from the large crack, so that the caulk is flush with a surface of the existing material; if the repair needed is a void: applying a urethane sealant to an interior surface of the void; applying a catalyzed cementitious mixture over the sealant so that excess catalyzed mixture protrudes from a surface of the existing material; allowing the catalyzed mixture to partially set; and removing the excess catalyzed mixture around and protruding from the void, so that the catalyzed mixture is flush with the surface of the existing material.

A method of substantially matching a user-selected color of an existing cementitious material includes: preparing a pigmented cementitious mixture having a hue similar to the user-selected color; refining color attributes of the pigmented mixture to substantially match the color attributes of the user-selected color; and confirming that the color attributes of the refined pigmented mixture substantially match the color attributes of the-user-selected color.

A method of applying, via a sprayer, a refined pigmented cementitious mixture having color attributes which substantially match color attributes of a user-selected color of an existing cementitious material includes: pouring the mixture through a strainer into the sprayer; tuning the sprayer for user-selected mixture discharge characteristics; and selectively spraying the mixture over part of the existing material.

Advantageously, crack and void repairs in the existing material are cosmetically unnoticeable. The refined pigmented mixture need only be applied over discolored or repaired portions of the existing material as the color attributes of the refined pigmented mixture substantially match the color attributes of the user-selected color. A majority of the existing material remains untouched thereby reducing user time and expense and increasing user efficiency in stucco repair and maintenance. Furthermore the refined pigmented mixture is prepared above 25 wt. % base cementitious powder to water—a paint consistency—to spray apply. Only one spray application of the refined pigmented mixture is needed for adequate coverage.

### BRIEF DESCRIPTION OF THE DRAWINGS

For a fuller understanding of the nature and advantages of the present application, as well as the preferred mode of use, reference should be made to the following detailed description read in conjunction with the accompanying drawings:

FIG. 1 is a photograph of components of a kit for repair, maintenance and substantial color-match of existing cementitious materials;

FIG. 2. is a flowchart which describes a general exemplary method of maintenance of the existing material;

FIG. 3 is a flowchart which describes an exemplary method of repair of the existing material;

FIG. 4 is a flowchart which describes a general exemplary method of substantially matching a user-selected color of the existing material;

FIG. 5 is a flowchart which describes a more detailed exemplary method of substantially matching the user-selected color of the existing material; and

FIG. 6 is a flowchart which describes an exemplary method of applying, via a sprayer, a refined mixture having color attributes which substantially match color attributes of the user-selected color over discolored portions of the existing material.

### DETAILED DESCRIPTION OF THE PREFERRED EMBODIMENTS

The following description incorporates the best embodiment presently contemplated for carrying out the present application. This description is made for the purpose of illustrating the general principles of the present application and is not meant to limit the inventive concepts claimed herein.

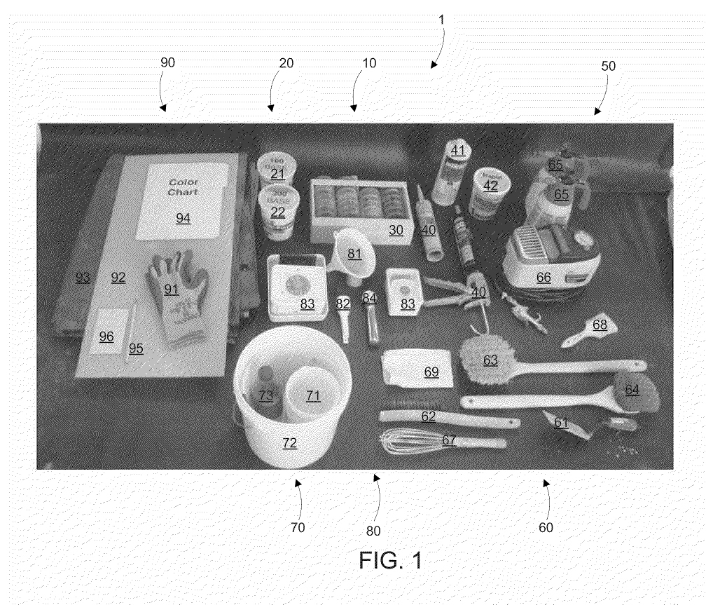

Kits for and methods of repair, maintenance and substantial color-match of existing cementitious materials are disclosed. Referring to FIG. 1, a kit 1 for repair, maintenance and substantial color-match of a user-selected color of an existing cementitious material may include a plurality of materials 10 which may include: a plurality of base cementitious powders 20 for preparing a base cementitious mixture comparable to a base of the existing material either for substantially matching a user-selected color of, repairing the existing material or both; a plurality of pigment oxides 30 for refining the base mixture into a refined pigmented cementitious mixture having color attributes which substantially match the color attributes of the user-selected color; a quick-setting mortar repair caulk 40 for repairing large cracks in the existing material; a urethane sealant 41 for repairing voids in the existing material; and a catalyzed cementitious powder 42 for preparing a catalyzed cementitious mixture for repairing voids in the existing material. Repair, maintenance and substantial color-match kit 1 also includes a plurality of implements 50 including: a plurality of applying and removing means 60 for applying and removing either the materials, mixtures or both; a plurality of containing means 70 for containing either the materials, mixtures or both; a plurality of measuring means 80 for measuring the materials; and a plurality of accessories 90.

Powders 20 may include a gray base cementitious powder 21 or a white base cementitious powder 22 composed of Portland cement, hydrated lime and other additives. Manufacturers may formulate cementitious products like stucco and fog coat from either gray powder 21, white powder 22 or both gray and white powders 21 and 22.

Pigment oxides 30 may be made from metal oxides and other inorganic compounds and minerals. Those with the longest history of proven performance in cementitious products are made from oxidized metals including: iron which form red, brown, orange, tan, yellow, purple and black; chrome which forms green; and cobalt which forms blue. With this basic pallet of colors nearly all common stucco colors may be created by proportional mixing of the oxidixed metals. Manufacturers market stucco and other cementitious materials including fog coat with color charts which display their possible colors.

Caulk 40 may be made from a limestone, marble or other sanded acrylic polymer. One example of such caulk 40 is sold under the trade name Quikrete Mortar Repair Caulk. Sealant 41 may be made from polyurethane polymers, plasticizers, fillers and other additives. One such sealant is sold under the trade name Sikaflex® Construction Sealant. Catalyzed powder 42 is quick setting and may be made from hydraulic cement and sand. One such catalyzed powder is sold under the trade name Rapid Set® Mortar Mix.

Applying and removing means 60 may include: a trowel 61 for applying and removing prepared catalyzed powder 42; a wire brush 62 for cleaning the existing material, removing excess caulk 40 and removing excess prepared catalyzed powder 42; an exploded nylon brush 63 for removing and cleaning excess prepared powders 20 (various cementitious mixtures including a base cementitious mixture, a pigmented cementitious mixture, a refined cementitious mixture) and feathering prepared and substantially color-matched prepared powders 20 (the refined mixture); a nylon brush 64 for applying and removing excess caulk 40 and for removing and cleaning excess various mixtures; a plurality of sprayers 65 for spraying the refined mixture and cleaning implements 50 and surrounding areas); a compressor with an air gun 66 for pressurizing sprayers 65; a whisk 67 for mixing the various mixtures; a paint brush 68 for applying sealant 41 and applying and mixing the various mixtures; and a rag 69 for applying and removing excess caulk 40 and for removing and cleaning excess various mixtures. Containing means 70 may include: a plurality of resealable containers 71 of various sizes including several oz. sized containers for containing pigment oxides 30 and qt. sized containers for containing and mixing various materials and mixtures; a plurality of buckets 72 for mixing and containing various mixtures and water for cleaning; and a plurality of bottles 73 for containing water for various mixtures. Measuring means 80 may include: a strainer funnel 81 for pouring the and straining particulate from the refined mixture; a plurality of measuring spoons 82 of various sizes for measuring various materials; a plurality of scales 83 of various sizes for weighing various materials and mixtures; and a scoop 84 for transferring various materials and mixtures. Accessories 90 may include: gloves 91 for user hand protection and applying caulk 40; a spray shield 92 for accurately applying the refined mixture; a plurality of tarps 93 for covering surrounding areas; a color chart 94 for substantially color matching the existing material which may include formulas for obtaining the exhibited colors; a writing utensil 95 for recording user additions of various materials; and paper 96 for recording user additions of various materials.

Note that the purposes, uses and sizes indicated for materials 10 and implements 50 of kit 1 are merely examples and should not be interpreted as exclusive or limiting.

A kit 1′ (not shown in the FIGS.) for substantial color-match of the user-selected color of the existing material may include a plurality of materials 10′ which may include: powders 20′; and pigment oxides 30′ for refining the base mixture into a refined pigmented cementitious mixture having color attributes which substantially match the color attributes of the user-selected color. Kit 1′ also may include a plurality of implements 50′ which may include: elements of applying and removing means 60′; elements of containing means 70′; elements of measuring means 80′; and elements of accessories 90′.

Note that the elements, purposes, uses and sizes indicated for materials 10 and implements 50 of kit 1 and for materials 10′ and implements 50′ of kit 1′ are merely exemplary and should not be interpreted as exclusive or limiting.

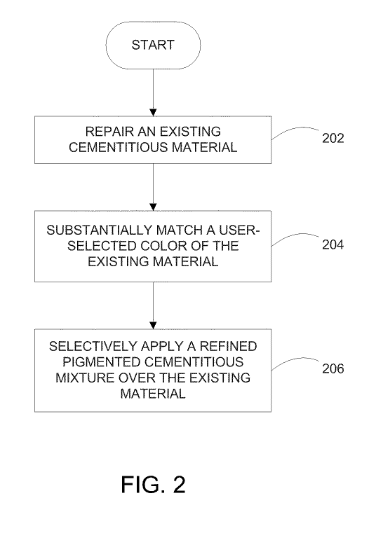

Referring to FIGS. 2-6, exemplary methods of repair, maintenance and substantial color-match of the existing cementitious material are disclosed. Components of kit 1 of FIG. 1 will be referenced with the flowchart steps of FIGS. 2-6.

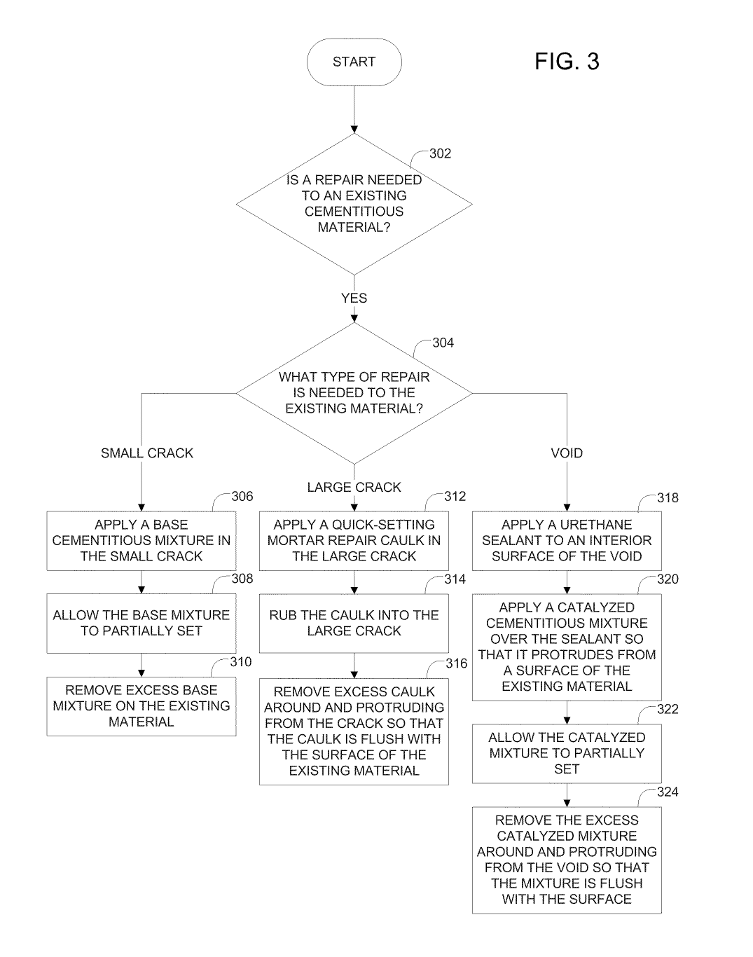

In FIG. 2 a general exemplary method of maintenance of the existing material is disclosed. Step 202 corresponds to repair of the existing material. Step 204 corresponds to substantial color-match of the existing material. Step 206 corresponds to selective application of the color-matched material over the existing cementitious material. Flowchart steps of FIGS. 3-6 will be referenced with the flowchart steps of FIG. 2.

In FIG. 3 a method of repair of the existing material is disclosed which corresponds to step 202 of FIG. 2. In step 302 the user determines whether repair is needed to the existing material. If so the user determines what type of repair is needed to the existing material which corresponds to step 304. If not the user substantially matches the user-selected color of the existing material which corresponds to step 204 of FIG. 2.

If the repair needed is a small crack the user applies a cementitious mixture using brush 68 which corresponds to step 306. The cementitious mixture consists of about 10 to about 20 wt. % powders 20 and about 80 to about 90 wt. % water. The milky consistency of the cementitious mixture allows it to flow with capillary action and fill the small crack. In step 308 the user allows the applied cementitious mixture to partially set—about 30 sec. to about 2 min. In step 310 the user removes excess cementitious mixture on the existing material around the small crack with brushes 63 and 64. The remaining cementitious mixture sets in the small crack and hardens flush with the surface of the existing material thereby creating a cosmetically unnoticeable repair. Note that steps 306, 308 and 310 of FIG. 3 may be repeated either once or a plurality of times either on the same or another small crack.

If the repair needed is a large crack the user applies caulk 40 which corresponds to step 312. The user places an angled tip of the caulk 40 tube against the surface of the existing material and applies a flat bead of caulk 40 along portions of the large crack at a time. In step 314 the user quickly rubs the applied caulk 40 into the crack with a gloved 91 hand. In step 316 the user removes excess caulk 40 around and protruding from the large crack with brush 64 or rag 69 so that the applied caulk 40 is flush with the surface of the existing material thereby creating a cosmetically unnoticeable repair. Note that steps 312, 314 and 316 of FIG. 3 may be repeated either once or a plurality of times either on the same or another large crack.

If the repair needed is a void the user applies sealant 44 to an interior surface of the void which corresponds to step 318. In step 320 the user applies a catalyzed cementitious mixture over the sealant using trowel 61 so that excess catalyzed mixture protrudes by about ⅛″ to about ½″ from the surface of the existing material. The catalyzed mixture consists of about 40 to about 60 wt. % catalyzed powder 42 and about 40 to about 60 wt. % water. The clay-like consistency of the catalyzed mixture, which is substantially thicker than manufacturer instructed, allows for single application to full depth, no shrinkage during curing unlike industry filler and quicker set time due to less water. In step 322 the user allows the applied catalyzed mixture to partially set for about 3 to about 10 minutes. In step 324 the user removes the excess catalyzed mixture around and protruding from the void with wire brush 62 so that the catalyzed mixture is flush with the surface of the existing material thereby creating a cosmetically unnoticeable repair.

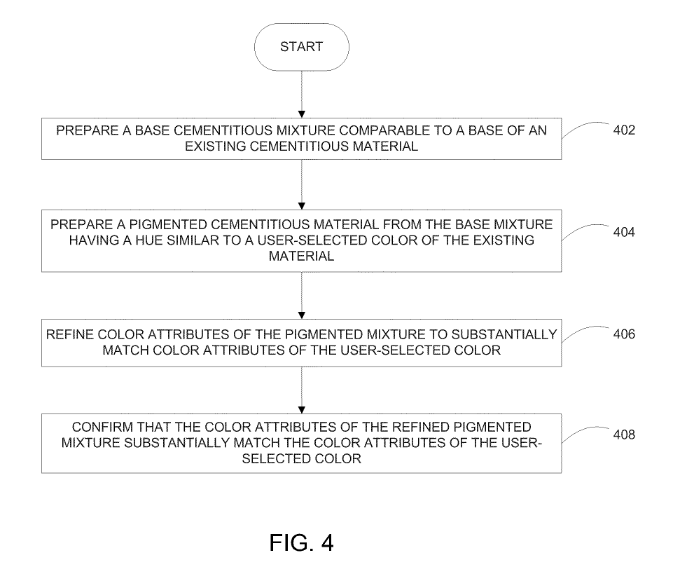

Referring now to FIG. 4 a general exemplary method of substantially matching the user-selected color of the existing material is disclosed which corresponds to step 204 of FIG. 2. Advantageously the refined pigmented mixture need only be applied over discolored or repaired portions of the existing material as the color attributes of the refined mixture substantially match the color attributes of the user-selected color. A majority of the existing material remains untouched thereby reducing user time and expense and increasing user efficiency in stucco repair and maintenance.

In step 402 the user prepares the base cementitious mixture comparable to the base of the existing material. In step 404 the user prepares the pigmented cementitious mixture from the base mixture having a hue similar to the user-selected color of the existing material. In step 406 the user refines color attributes of the pigmented mixture to substantially match the color attributes of the user-selected color. In step 408 the user confirms that the color attributes of the refined pigmented mixture substantially match the color attributes of the user-selected color. Ideally with the method of FIG. 4 the user substantially matches the color attributes of the user-selected color to within about ±5%.

The user-selected color of the existing material has average color attribute values of properly colored portions of the existing material. That is the user-selected color is chosen as the average color of all non-stained and non-damaged portions of the existing material. These color attributes include hue, colorfulness, chroma, saturation, lightness and brightness. With three color attributes—colorfulness (or chroma or saturation), lightness (or brightness), and hue—any color can be described.

In color theory, a hue refers to a pure color and is defined as the degree to which a stimulus can be described as similar to or different from stimuli that are described as red, green, blue, and yellow—the unique hues. Colors with the same hue are distinguished with adjectives referring to their lightness and/or chroma, such as with light blue, pastel blue, etc. Exceptions include brown, which is a dark orange, and pink, a light red with reduced chroma.

In color theory, colorfulness, chroma, and saturation are related but distinct concepts referring to the perceived intensity of a specific color. Colorfulness is the difference between a color against gray. A highly colorful stimulus is vivid and intense, while a less colorful stimulus appears more muted, closer to gray. With no colorfulness at all, a color is a neutral gray. Chroma is the difference of a color against the brightness of another color which appears white under similar viewing conditions. Saturation is the difference of a color against its own brightness. The saturation of a color is determined by a combination of light intensity and how much it is distributed across the spectrum of different wavelengths. The purest color is achieved by using just one wavelength at a high intensity. If the intensity drops, so does the saturation. To desaturate a color the user may add white, black, gray, or the hue's complement.

It is common among painters to darken a color by adding black paint—producing colors called shades with reduced lightness—or lighten a color by adding white—producing colors called tints with increased lightness. Tints are also produced by mixing gray shades. Mixing with any neutral color, including black and white, reduces chroma or colorfulness and shifts its hue. For instance darkening a color by adding black can cause colors such as yellows, reds and oranges to shift toward the greenish or bluish part of the color light spectrum. Lightening a color by adding white can cause a shift towards blue when mixed with reds and oranges. Another practice when darkening a color is to use its opposite, or complementary, color in order to neutralize it without a shift in hue, and darken it if the additive color is darker than the parent color. When lightening Is a color the hue shift can be corrected with the addition of a small amount of an adjacent color to bring the hue of the mixture back in line with the parent color.

Gloss is an optical property of material appearance, which is based on the interaction of light with physical characteristics, or topography, of a surface—the ability of a surface to reflect light into a specular direction. Factors that affects gloss are the refractive index of the material, the angle of incident light and the surface topography. Material with smooth surface appears glossy while very rough surfaces, like stucco, reflect no specular light and therefore appear matte.

Additional color theories affect how the user-selected color of the existing material is chosen and how the user matches that color including: subjective color perception (color vision, perception in the eye and brain and deficiency); physics of light (wavelength, frequency interval, and energy of the spectral colors); surface properties of the existing material; transmission properties of the various mixtures (reflectivity, opaqueness, translucency and transparency); emission properties of the various mixtures (absorption and emission); dichromatism—where the hue of the refined mixture is dependent on concentration and thickness of the existing material; weather and ambient conditions (shade or direct sunlight, temperature, time of day and time of year); and color properties of other nearby objects.

The user must factor color attributes and additional color theories of the various mixtures and the existing material during substantial color-match because, for example, a plurality of shades and tints of color are exhibited on texture of as well as sun-exposed and shade-exposed portions of the existing material and the various applied mixtures. The pigment oxides in stucco may tint (have lower colorfulness, chroma and saturation values and higher brightness and lightness values) on sun-exposed and shade (have higher colorfulness, chroma and saturation values and lower brightness and lightness values) on shade-exposed portions of the existing material both over time and during the drying process. Also the pigment oxides in stucco may tint on higher portions of the existing material and shade on lower portions of the existing material over time. If the user is to substantially color match the existing material on an entire structure several areas of the existing material will need to be tested. Thus the refined mixture will likely have a higher lightness color attribute value than the user-selected color—the user's target color. This ensures that application(s) of the refined mixture(s) age(s) properly with the existing material.

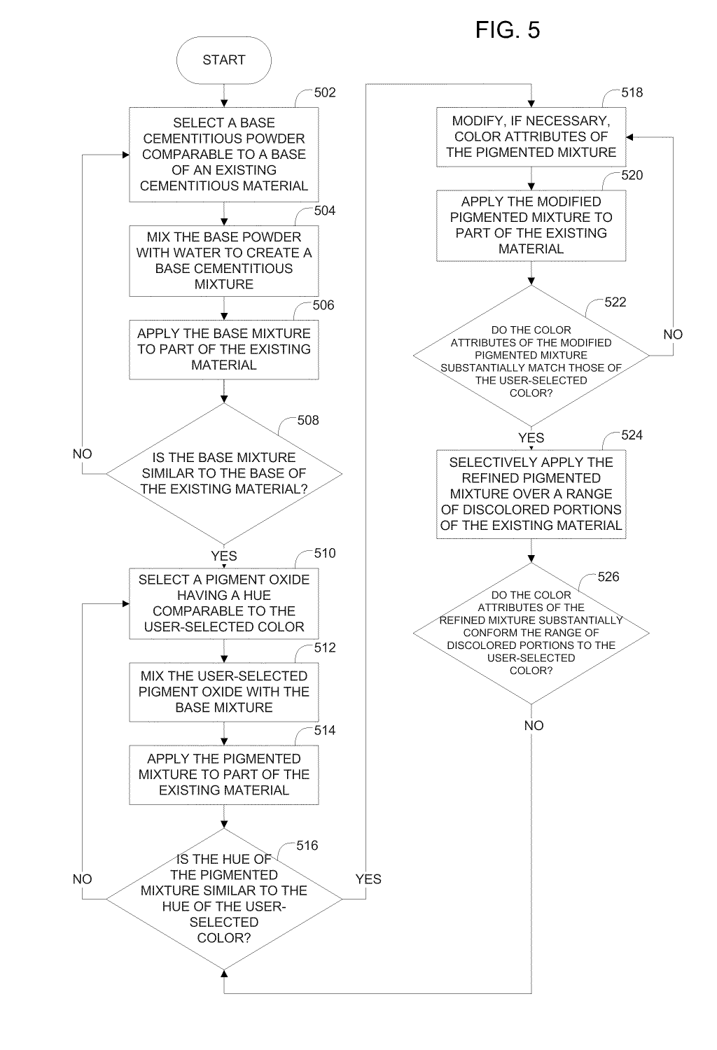

Flowchart steps of FIG. 4 will be referenced with the flowchart steps of FIG. 5. Flowchart steps 502, 504, 506 and 508 correspond to flowchart step 402. Flowchart steps 510, 512, 514 and 516 correspond to flowchart step 404. Flowchart steps 518, 520 and 522 correspond to flowchart step 406. Flowchart steps 524 and 526 correspond to flowchart step 408.

Step 402 of FIG. 4 (steps 502, 504, 506 and 508 of FIG. 5) may not need to be performed because the user either knows or can determine what the base of the existing material is by observation. If not step 402 of FIG. 4 must be performed.

In step 502 of FIG. 5 the user selects from powders 20 a powder comparable to the base of the existing material (either gray powder 21, white powder 22 or both gray and white powders 21 and 22). In step 504 the user mixes water and the selected powder 20 in a qt. size container 71 to form the base mixture, or Stucco Cream™. The base mixture has about 25 to about 40 wt. % selected powder 20 and about 60 to about 75 wt. % water—substantially more viscous than the milky consistency of industry standards. In step 506 the user applies the base mixture with paint brush 68 to part of the existing material which exhibits the user-selected color. After applying, in a step not shown in FIG. 5, the user allows the base mixture to substantially dry on the existing material. This drying step may take between about 5 min. to about 20 min. depending on ambient conditions.

In step 508 the user determines whether the base mixture is similar to the base of the existing material. The user must factor color attributes and additional color theories of the various mixtures and the existing material in this determination. If so the user prepares the pigmented cementitious mixture having hue similar to the user-selected color, which corresponds to step 404 of FIG. 4. If not the user repeats the step of preparing the base mixture with a different powder 20 which corresponds to step 402 of FIG. 4.

Note that steps 502, 504, 506 and 508 may be repeated either once or a plurality of times. Additionally steps 502, 504 and 506 may be performed simultaneously with a plurality of base powders 20 to increase efficiency. If any tested base mixture is discarded the user should clean used qt. container 71. The user should clean brush 68 as well.

In step 404 of FIG. 4 the user prepares the pigmented mixture from the base mixture having hue similar to the user-selected color. Flowchart steps 510, 512, 514 and 516 of FIG. 5 correspond to flowchart step 404.

In step 510 of FIG. 5 the user selects a pigment oxide from the plurality of pigment oxides 30 having hue comparable to the user-selected color. In practice the user selects a color having the selected base and comparable hue from color chart 94, but may proceed without use of color chart 94. In step 512 the user mixes selected pigment oxide 30 with the base mixture in qt. size container 71 to form the pigmented mixture having about 25 to about 40 wt. % selected powder 20, about 60 to about 75 wt. % water and about 1 to about 10 wt. % selected pigment oxide 30. In step 514 the user applies the pigmented mixture with paint brush 68 to part of the existing material which exhibits the user-selected color. Ideally the user applies the pigmented mixture by brushing with graded intensity to observe incremental color changes. In other words the brush stroke should be about 3 to about 6 in. long that starts off firm and ends soft. Further the brush stroke should be applied to a flat portion of the existing material with minimal texture for greater visual clarity.

After applying, in. a step not shown in FIG. 5, the user allows the pigmented mixture to substantially dry on the existing material. This drying step may take between about 5 min. to about 20 min. depending on ambient conditions. Note that the user will observe the lightly brushed end of the brush stroke begin to dry before the firmly brushed end.

In step 516 the user determines whether the hue of the pigmented mixture is similar to the hue of the user-selected color. The user must factor color attributes and additional color theories of the various mixtures and the existing material in this determination. If so the user refines the color attributes of the pigmented mixture to substantially match the color attributes of the user-selected color which corresponds to step 406 of FIG. 4. If not the user repeats the step of either preparing a base mixture with a different powder 20 which corresponds to step 402 or preparing a pigmented mixture with a different pigment oxide 30 which corresponds to step 404.

Note that steps 510, 512, 514 and 516 of FIG. 5 may be repeated either once or a plurality of times. Additionally steps 510, 512, 514 and 516 may be performed simultaneously with a plurality of pigment oxides 30 to increase efficiency. If any pigmented mixture is discarded the user should clean used container 71.

In step 406 of FIG. 4 the user refines color attributes of the pigmented mixture to substantially match the color attributes of the user-selected color thereby forming the refined mixture. Flowchart steps 518, 520 and 522 of FIG. 5 correspond to flowchart step 406.

In step 518 of FIG. 5 the user modifies, if necessary, color attributes of the pigmented mixture. The user determines whether differences in color attributes including hue, colorfulness, chroma, saturation, lightness and brightness either individually, separately or in combination exist between the pigmented mixture and the existing material. If the color attributes of the pigmented mixture substantially match the color attributes of the user-selected color the user performs the step of confirming which corresponds to step 408 of FIG. 4.

Generally if the color attributes of the pigmented mixture vary from the color attributes of the user-selected color the user mixes white, black, gray and complementary-colored pigment oxides of pigment oxides 30 and gray, white and both gray and white powders 21 and 22, either individually, separately or in combination with the pigmented mixture. The user mixes the additional refining pigment oxides 30 or base powders 20 with the pigmented mixture in qt. size container 71 to form the refined pigmented mixture having about 25 to about 40 wt. % selected powder 20, about 60 to about 75 wt. % water and about 1 to about 10 wt. % selected and refining pigment oxides 30.

Examples of modifications include mixing with the pigmented mixture: a neutral pigment oxide if the pigmented mixture is more saturated; additional user-selected pigment oxide 30 or black pigment oxide if the pigmented mixture is lighter; or additional user-selected base powder 20 if the pigmented mixture is darker. The user must factor color attributes and additional color theories of the various mixtures and the existing material in this determination.

In step 520 the user applies the modified pigmented mixture with paint brush 68 to part of the existing material which exhibits the user-selected color. Ideally the user applies the modified mixture by brushing with graded intensity to observe incremental color changes. In other words the brush stroke should be about 3 to about 6 in. long that starts off firm and ends soft. Further the brush stroke should be applied to a flat portion of the existing material with minimal texture for greater visual clarity.

After applying, in a step not shown in FIG. 5, the user allows the modified mixture to substantially dry on the existing material. This drying step may take between about 5 min. to about 20 min. depending on ambient conditions. Note that the user will observe the lightly brushed end of the brush stroke begin to dry before the firmly brushed end.

In step 522 the user determines whether the color attributes of the modified mixture substantially match the color attributes of the user-selected color. The user must factor color attributes and additional color theories of the various mixtures and the existing material in this determination. If so the user confirms that the color attributes of the modified mixture substantially match the color attributes of the user-selected color which corresponds to step 408 of FIG. 4. If not the user repeats the step of either refining with the modified mixture which corresponds to step 406, preparing a pigmented mixture with a different pigment oxide 30 which corresponds to step 404, or preparing a base mixture with a different base powder 20 which corresponds to step 402, depending on the situation.

Note that steps 518, 520 and 522 of FIG. 5 may be repeated either once or a plurality of times. Additionally steps 518, 520 and 522 may be performed simultaneously with a plurality of modifications to increase efficiency. If any modified mixture is discarded the user should clean used container 71.

In step 408 of FIG. 4 the user confirms that the color attributes of the refined pigmented mixture substantially match the color attributes of the user-selected color. Flowchart steps 524 and 522 of FIG. 5 correspond to flowchart step 408.

In step 524 of FIG. 5 the user selectively applies the refined mixture over a range of discolored portions of the existing material. The range of discolored portions of the existing material is variations in its color attributes.

Ideally the user selectively applies the refined mixture by spraying with sprayer 65 and spray shield 92 using a feathering application technique to observe incremental color changes. In other words the spray application should be about 3 to about 6 ft. long that starts just above the weep screed and travels vertically up the existing material through both discolored and properly colored areas along an edge of spray shield 92. The user should observe the spray application of the refined mixture blend in completely with the existing material. This application provides a gauge by which the user is able to determine how substantial, or cosmetically credible, the color match of the refined mixture is. See discussion related to step 206 of FIG. 2 below for further information on applying the refined mixture via sprayer 65 and feathering techniques.

After applying, in a step not shown in FIG. 5, the user allows the refined mixture to substantially dry on the existing material. This drying step may take between about 5 min. to about 20 min. depending on the weather and ambient conditions during application.

In step 526 the user determines whether the color attributes of the refined mixture substantially conforms the range of discolored portions to the user-selected color. The user must factor color attributes and additional color theories of the various mixtures and the existing material in this determination. If so the user has substantially matched the user-selected color of the existing material, may mix an acrylic bonder material with the refined mixture and may prepare a larger batch of refined mixture with the bonder using the same ratios of materials to complete the method of maintenance of the existing material disclosed in FIG. 2. Thus the refined mixture may have about 25 to about 40 wt. % selected powder 20, about 60 to about 75 wt. % water, about 1 to about 10 wt. % selected and refining pigment oxide(s) 30 and about 0.3 to about 3 wt. % bonder material. Ideally with the method of FIG. 4 the user substantially matches the color attributes of the user-selected color to within about ±5%. If not the user repeats the step of either refining with the modified mixture which corresponds to step 406 of FIG. 4, or preparing a pigmented mixture with a different pigment oxide 30 which corresponds to step 404, or preparing a base mixture with a different base powder 20 which corresponds to step 402, depending on the situation.

Note that steps 524 and 526 of FIG. 5 may be repeated either once or a plurality of times. Additionally steps 524 and 526 may be performed simultaneously with a plurality of refined mixtures to increase efficiency. If any refined mixture is discarded, the user should clean used container 71.

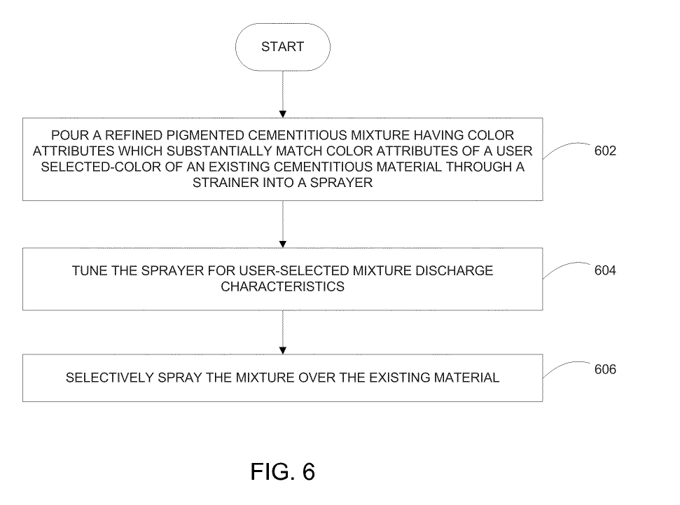

In FIG. 2 the general exemplary method of maintenance of the existing material is disclosed. In step 206 the method of applying, via a sprayer, the refined mixture having color attributes which substantially match the color attributes of the user-selected color over discolored portions of the existing material is disclosed. Steps 602, 604 and 606 of FIG. 6 correspond to step 206 of FIG. 2.

In step 602 the user pours the refined mixture through strainer funnel 81 into sprayer 65. The user securely tightens a top on sprayer 65. Ideally sprayer 65 is a multi-purpose pump sprayer but may be a hand-pump, compressed air tank, professional tank or a modified painter's airless sprayer. Ideally sprayer 65 has capacity of about 50 oz. but may have capacity of about 30 oz. to about 100 oz. Sprayer 65 should be about 40% to about 70% filled with refined mixture to ensure adequate air pressure of about 40 psi to about 60 psi to discharge all of the refined mixture. Strainer funnel 81 may have sieve size of mesh #32. Note that funnel strainer 81 has a limited life span. Strainer funnel 81 should be cleaned after each use by immersion, small end first, in a 5 gal. size bucket 72 of water then thorough rinsing with water by the other sprayer 65. It is necessary to clean strainer funnel 81 for the next refined mixture to ensure that no particulate contaminates sprayer 65 otherwise a tip of sprayer 65 will clog.

In step 604 the user tunes sprayer 65 to achieve user-selected refined mixture discharge characteristics. The step of tuning includes pressurizing sprayer 65 and adjusting the tip of sprayer 65 to discharge a substantially drip-free and drift-free spray of refined mixture. Sprayer 65 is pressurized by: connecting an air discharge end of compressor 66 to a mixture discharge orifice of sprayer 65; pulling a trigger of sprayer 65; activating compressor 66; allowing compressed air to flow into sprayer 65 from compressor 66; and, upon completion, simultaneously releasing the trigger of sprayer 65 and deactivating compressor 66. This pressurizing step may take between about 15 sec. to about 1 min. depending on the specifications of sprayer 65, compressor 66 and the refined mixture. After disconnection the user should activate the air gun to discharge any residual refined mixture which may have entered the air discharge end during pressurization.

Adjusting the tip of sprayer 65 to discharge a substantially drip-free and drift-free spray of the refined mixture includes lightly tightening the tip until it is fully closed and then opening it one half turn. The user should perform a test spray into bucket 72. When the tip is over tightened it will produce a fine mist of refined mixture, which often will clog the tip. Conversely if the tip is too open the refined mixture spray will come out in droplets. When the tip is tightened correctly sprayer 65 makes a whooshing sound and handles like an airbrush and refined mixture spray is substantially drip-free and drift-free.

Sprayer 65 operation tips include: 1) ensuring that strainer funnel 81 is both clean and useable if sprayer 65 frequently clogs during use; 2) properly tightening the tip of sprayer 65; 3) timely spraying the refined mixture within about 30 min. as it tends to settle to the bottom; 4) laying tarps 93 prior to filling sprayer 65 to ensure timely spraying; 5) vibrating or agitating the refined mixture during and between applications to ensure proper mixing and avoid hardening and settling to the bottom; and 6) cleaning the mixture discharge orifice of sprayer 65 by air flow either in air, immersed in water or both.

In step 604 the user selectively sprays the refined mixture over part of the existing material by feathering the mixture over the range of discolored portions to substantially conform the range to the user-selected color. Applied to fog coat, feathering is an application technique of softening/blurring/smoothing edges of the applied refined mixture so that it blends into the existing material with substantially no contrast. Feathering may be achieved by: adjusting the spray intensity of the refined mixture depending on the user's factoring of refined mixture and existing material color attributes and additional color theories; or blending with brushes 63 or 64 spray remains of the refined mixture into adjacent existing material. Advantageously the refined mixture is prepared above 25 wt. % base powder 20 to water—a paint consistency—to spray apply. Only one spray application of the refined mixture is needed for adequate coverage. Further the thicker consistency of the refined mixture results in: substantially drip-free and drift-free spray—it hits the existing material and remains; faster drying time; and easier clean-up.

In a step not shown in FIG. 6 the user cleans sprayer 65, surrounding areas and other components of kit 1. Once all of the refined mixture has been removed from sprayer 65 it must be cleaned by: filling it with clean water; pressurizing it; spraying the water through it; emptying it; refilling it with clean water; repressurizing it; partially spraying the water through it; and storing it pressurized. The user cleans the refined mixture before it hardens from surrounding areas including the ground and concrete, wood, glass and metal surfaces with nylon brushes 63 and 64. The user also cleans other components of kit 1 with water.

In step 204 of FIG. 4, the user substantially matches the user-selected color of the existing material. While preparing the base mixture, preparing the pigmented mixture and refining the pigmented mixture the user should record, either manually with pen 95 and paper 96 or electronically, any addition of materials 10 to create a formula for the refined mixture. The user needs this information to prepare a larger batch of the refined mixture using the same ratios of materials 10 to complete the method of maintenance of the existing material disclosed in FIG. 2.

Note that the user may perform the determining steps in step 204 of FIG. 4 either analytically, electronically or visually. For example, the user may be able to analyze the existing material by mass spectroscopy which would analytically provide the relative amounts of cementitious and pigment oxide materials. Additionally paint manufacturers and distributers may use spectrophotometers to electronically match a color sample quickly and precisely, but often require a color chip or sample material with a consistent color and finish. The user may be able to combine electronic and visual techniques to substantially match the color attributes of the user-selected color. For example, the user may: attach color chart 94 to the existing material; take a picture; import the picture into a graphics software program; sample the existing material; set the fill color of a square in a new document as the sampled color of the existing material; draw several small squares within the large square; sample several colors on color chart 94 in the picture; set the fill color of the small squares as the sampled colors on color chart 94 in the new document; and visually determine a starting color for the method of substantial color-match.

### Example: Repair of an Existing Cementitious Material

To repair a small crack the user: mixes 33 wt. % base powder 20 with 67 wt. % water to form the Stucco Cream™; mixes additional water to form a less viscous Stucco Cream®) of 25 wt. % base powder 20 with 75 wt. % water; applies the less viscous Stucco Cream™ to the small crack with brush 68 (step 306); allows the less viscous Stucco Cream™ to flow into the small crack; allows the less viscous Stucco Cream™ to set for 30 sec. (step 308); and removes with brushes 64 then 63 the excess less viscous Stucco Cream™ from the existing material leaving behind the less viscous Stucco Cream™ in the small crack (step 310).

To repair a large crack the user: holds an angled tip of the caulk 40 tube flat against the existing material; applies a 6 in. to 1 ft. flat bead of caulk 40 along the large crack (step 312); immediately rubs the applied caulk 40 in the large crack with a gloved 40 hand (step 314); and immediately removes with brush 62 any excess caulk 40 off of the existing surface (step 316).

To repair a void the user: applies sealant 41 to an interior surface of the void (step 318); mixes with trowel 61 50 wt. % catalyzed powder 42 with 50 wt. % water; applies with trowel 61 the catalyzed mixture into the void leaving ¼ in. excess mixture protruding from the existing material (step 320); allows the catalyzed mixture to set for 5 min. (step 322); and removes the protruding catalyzed mixture (step 324).

### Example: Substantial Color-Match of a User-Selected Color of an Existing Cementitious Material

To substantially color-match a user-selected color of an existing cementitious material the user: mixes grey-base and white-base Stucco Cream™ (steps 502 and 504); applies with brush 68 both Stucco Creams™ to the existing material (step 506); allows both Stucco Creams™ to dry; determines which base the color of the existing material is (step 508); selects from color chart 94 the closest color having the determined base of the existing material (step 510); mixes 1 wt. % chosen pigment oxide 30 to the determined Stucco Cream™ (step 512); applies the pigmented Stucco Cream™ to the existing material (step 514); allows the pigmented Stucco Cream™ to dry; determines whether a hue of pigmented Stucco Cream™ is similar to the user-selected color (step 516); modifies, if necessary, color attributes of the pigmented Stucco Cream™ by incrementally adding selected powders 20 and various pigment oxides 30 (step 518); applies the modified pigmented Stucco Cream™ to the existing material (step 520); allows the modified pigmented Stucco Cream™ to dry; determines whether the color attributes of the modified pigmented Stucco Cream™ substantially match the color attributes of the user-selected color (step 522); selectively applies via sprayer 65 the refined pigmented Stucco Cream™ over a range of discolored portions of the existing material (step 524); and determines whether the color attributes of the refined pigmented Stucco Cream™ conform the range of discolored portions to the user-selected color (step 526).

### Example: Selective Application of a Refined Cementitious Mixture Over an Existing Cementitious Material

To spray the refined Stucco Cream™ the user: pours the refined Stucco Cream™ through a strainer into sprayer 65 (step 602); tunes sprayer 65 for substantially drip-free and drift-free spray of refined Stucco Cream™ (step 604); and feathering the refined Stucco Cream™ over discolored and repaired portions of the existing material (step 606).

Final Comments. It is to be understood that the above is merely a description of preferred embodiments of the present application and that various changes, combinations, alterations, and variations may be made without departing from the true spirit and scope of the invention as set for in the appended claims. The kits for and methods of repair, maintenance and substantial color match of cementitious materials of the present application are described in relation to stucco as examples. However, they are viable for use in other residential, commercial, and industrial applications, as well as other cementitious materials all together. Few if any of the terms or phrases in the specification and claims have been given any special meaning different from their plain language meaning, and therefore the specification is not to be used to define terms in an unduly narrow sense.

What is claimed is:

1. A method of substantially matching a user-selected color of an existing cementitious material including:
preparing a pigmented cementitious mixture having a hue similar to the user-selected color; and
refining color attributes of the pigmented mixture to substantially match the color attributes of the user-selected color.

2. The method of claim 1 including:
confirming that the color attributes of the refined pigmented mixture substantially match the color attributes of the user-selected color.

3. The method of claim 2 including:
prior to the step of preparing the pigmented mixture, preparing a base cementitious mixture comparable to a base of the existing material.

4. The method of claim 1 wherein the step of preparing includes:
selecting a pigment oxide having a hue comparable to the user-selected color;
mixing the user-selected pigment oxide with a base cementitious mixture comparable to a base of the existing material;
applying the pigmented mixture to part of the existing material;
determining whether the hue of the pigmented mixture is similar to the hue of the user-selected color:
if not, repeating the step of preparing; and
if so, performing the step of refining.

5. The method of claim 1 wherein the step of refining includes:
modifying, if necessary, color attributes of the pigmented mixture;
applying the modified pigmented mixture to part of the existing material;
determining whether the color attributes of the modified pigmented mixture substantially match the color attributes of the user-selected color:
if not, repeating the step of refining; and
if so, performing a step of confirming.

6. The method of claim 2 wherein the step of confirming includes:
selectively applying the refined pigmented mixture over a range of discolored portions of the existing material;
determining whether the color attributes of the refined pigmented mixture substantially conform the range of discolored portions to the user-selected color:
if not, repeating either the step of preparing, refining or both.

7. The method of claim 1 including:
wherein the step of preparing includes:
selecting a pigment oxide having a hue comparable to the user-selected color;
mixing the user-selected pigment oxide with a base cementitious mixture comparable to a base of the existing material;
applying the pigmented mixture to part of the existing material;
determining whether the hue of the pigmented mixture is similar to the hue of the user-selected color:
if not, repeating the step of preparing;
if so, performing the step of refining;
wherein the step of refining includes:
modifying, if necessary, color attributes of the pigmented mixture;
applying the modified pigmented mixture to part of the existing material;
determining whether the color attributes of the modified pigmented mixture substantially match the color attributes of the user-selected color:
if not, repeating the step of refining; and
if so, performing a step of confirming.

8. The method of claim 2 including:
wherein the step of preparing includes:
selecting a pigment oxide having a hue comparable to the user-selected color;
mixing the user-selected pigment oxide with a base cementitious mixture comparable to a base of the existing material;
applying the pigmented mixture to part of the existing material;
determining whether the hue of the pigmented mixture is similar to the hue of the user-selected color:
if not, repeating the step of preparing;
if so, performing the step of refining;
wherein the step of refining includes:
modifying, if necessary, color attributes of the pigmented mixture;
applying the modified pigmented mixture to part of the existing material;
determining whether the color attributes of the modified pigmented mixture substantially match the color attributes of the user-selected color:
if not, repeating the step of refining;
if so, performing a step of confirming;
wherein the step of confirming includes:
selectively applying the refined pigmented mixture over a range of discolored portions of the existing material;
determining whether the color attributes of the refined pigmented mixture substantially conform the range of discolored portions to the user-selected color:
if not, repeating either the step of preparing, refining or both.

9. The method of claim 3 wherein the step of preparing the base mixture includes:
selecting a base cementitious powder comparable to a base of the existing material;
mixing the user-selected cementitious powder with water to create the base mixture;
applying the base mixture to part of the existing material; and
determining whether the base mixture is similar to the base of the existing material:
if not, repeating the step of preparing the base mixture; and
if so, performing the step of preparing the pigmented mixture.

10. The method of claim 3 including:
wherein the step of preparing the base mixture includes:
selecting a base cementitious powder comparable to a base of the existing material;
mixing the user-selected cementitious powder with water to create the base mixture;
applying the base mixture to part of the existing material; and
determining whether the base mixture is similar to the base of the existing material:
if not, repeating the step of preparing the base mixture;
if so, performing the step of preparing the pigmented mixture;
wherein the step of preparing the pigmented mixture includes:
selecting a pigment oxide having a hue comparable to the user-selected color;
mixing the user-selected pigment oxide with the base mixture;
applying the pigmented mixture to part of the existing material;
determining whether the hue of the pigmented mixture is similar to the hue of the user-selected color:
if not, repeating either the step of preparing the base mixture or preparing the pigmented mixture;
if so, performing the step of refining;
wherein the step of refining includes:
modifying, if necessary, color attributes of the pigmented mixture;
applying the modified pigmented mixture to part of the existing material;
determining whether the color attributes of the modified pigmented mixture substantially match the color attributes of the user-selected color:
if not, repeating the step of refining;
if so, performing a step of confirming;
wherein the step of confirming includes:
selectively applying the refined pigmented mixture over a range of discolored portions of the existing material;
determining whether the color attributes of the refined pigmented mixture substantially conform the range of discolored portions to the user-selected color:
if not, repeating either the step of preparing the base mixture, preparing the pigmented mixture or refining.

11. The method of claim 5, 7, 8 or 10 wherein the step of modifying includes:
determining whether differences in color attributes including colorfulness, chroma, saturation, lightness, brightness and hue, either individually, separately or in combination, exist between the pigmented mixture and the existing material:
if the color attributes of the pigmented mixture substantially match the color attributes of the user-selected color, performing a step of confirming; and
if the color attributes of the pigmented mixture vary from the color attributes of the user-selected color, mixing white, black, gray and complementary-colored pigment oxide and base cementitious powder, either individually, separately or in combination, with the pigmented mixture.

12. The method of claim 1, 2 or 3 wherein the user-selected color has average color attribute values of properly-colored portions of the existing material.

13. The method of claim 1, 2 or 3 wherein the refined pigmented mixture has a higher lightness color attribute value than the user-selected color because the refined mixture may darken over time.

14. The method of claims 6, 8 or 10 wherein the range of discolored portions of the existing material are variations in the color attributes of the existing material over time.

15. The method of claim 10 wherein the steps of applying either the base mixture, pigmented mixture or refined mixture on the existing material are performed either by brushing with graded intensity to observe incremental color changes or by spraying with a feathering technique.

16. The method of claim 10 wherein the steps of preparing the base mixture, preparing the pigmented mixture and refining the pigmented mixture include recording, either manually or electronically, any addition of material to create a formula for the refined mixture.

17. The method of claim 10 wherein, after the steps of applying but prior to the steps of determining, allowing the mixtures to substantially dry.

18. The method of claim 10 wherein the steps of determining are performed either analytically, electronically or visually.

19. The method of claim 10 including:
wherein the base mixture includes about 25 to about 40 weight percent base powder and about 60 to about 75 weight percent water;
wherein the pigmented mixture includes about 25 to about 40 weight percent base powder, about 60 to about 75 weight percent water and about 1 to about 10 weight percent pigment oxide; and
wherein the refined mixture includes about 25 to about 40 weight percent base powder, about 60 to about 75 weight percent water, about 1 to about 10 weight percent pigment and about 0.3 to about 3 weight percent bonder material.

20. The method of claim 1 wherein the existing cementitious material is stucco.

21. A method of applying, via a sprayer, a refined pigmented cementitious mixture having color attributes which substantially match color attributes of a user-selected color of an existing cementitious material including:
pouring the refined mixture through a strainer into the sprayer;
tuning the sprayer for user-selected refined mixture discharge characteristics; and
selectively spraying the refined mixture over part of the existing material.

22. The method of claim 21 wherein the mixture either includes:
about 25 to about 40 weight percent base powder and about 60 to about 75 weight percent water;
about 25 to about 40 weight percent base powder, about 60 to about 75 weight percent water and about 1 to about 10 weight percent pigment oxide; or
about 25 to about 40 weight percent base powder, about 60 to about 75 weight percent water, about 1 to about 3 weight percent pigment and about 0.3 to about 3 weight percent bonder material.

23. The method of claim 22 wherein the step of tuning includes pressurizing the sprayer and adjusting a sprayer tip of the sprayer to discharge a substantially drip-free and drift-free spray of mixture.

24. The method of claim 23 wherein the step of selectively spraying includes:
feathering the mixture over a range of discolored portions of the existing material to substantially conform the range of discolored portions to the user-selected color of the existing material.

25. The method of claim 24 wherein the sprayer has a capacity of about 30 ounces to about 100 ounces.

26. The method of claim 25 including cleaning the sprayer, other components and surrounding areas.

27. The method of claim 21 wherein the existing material is stucco.

28. A method of repairing existing cementitious material including:
determining a type of repair needed to the existing material:
if the repair needed is a small crack:
applying a cementitious mixture in the small crack;
allowing the base mixture to partially set;
removing excess base mixture on the existing material around the small crack;
if the repair needed is a large crack:
applying a quick-setting mortar repair caulk in the large crack;
rubbing the caulk into the large crack;
removing excess caulk around and protruding from the large crack, so that the caulk is flush with a surface of the existing material;
if the repair needed is a void:
applying a urethane sealant to an interior surface of the void;
applying a catalyzed cementitious mixture over the sealant so that excess catalyzed mixture protrudes from a surface of the existing material;
allowing the catalyzed mixture to partially set; and
removing the excess catalyzed mixture around and protruding from the void, so that the catalyzed mixture is flush with the surface of the existing material.

29. The method of claim 28 wherein the cementitious mixture includes about 15 to about 30 weight percent base cementitious powder and about 70 to about 85 weight percent water.

30. The method of claim 28 wherein the existing material is stucco.

31. A method of repair, maintenance and substantial color-match of existing cementitious material including:
repairing the existing material including:
determining whether a repair is needed to the existing material:
if so, performing a step of determining a type of repair needed to the existing material;
if not, performing a step of substantially matching a user-selected color of the existing material;
determining the type of repair needed to the existing material including:
if the repair is a small crack:
applying a base cementitious mixture in the small crack;
allowing the base mixture to partially set;
removing excess base mixture on the existing material around the small crack;
if the repair is a large crack:
applying a quick-setting mortar repair caulk in the large crack;
rubbing the caulk into the large crack;
removing excess caulk around and protruding from the large crack, so that the caulk is flush with a surface of the existing material;
if the repair is a void:
applying a urethane sealant to an interior surface of the void;
applying a catalyzed cementitious mixture over the sealant so that excess catalyzed mixture protrudes from a surface of the existing material;
allowing the catalyzed mixture to partially set;
removing the excess catalyzed mixture around and protruding from the void, so that the catalyzed mixture is flush with the surface of the existing material;
substantially matching a user-selected color of the existing material including:
preparing a pigmented cementitious mixture having a hue similar to the user-selected color;
refining color attributes of the pigmented mixture to substantially match the color attributes of the user-selected color;
confirming that the color attributes of the refined pigmented mixture substantially match the color attributes of the user-selected color;
selectively applying, via a sprayer, the refined mixture including:
tuning the sprayer for user-selected refined mixture discharge characteristics; and
selectively spraying the refined mixture over part of the existing material.

32. The method of claim 31 wherein the existing material is stucco.

33. A kit for substantially matching a user-selected color of an existing cementitious material including:
a plurality of materials including:
a plurality of cementitious powders for preparing a base cementitious mixture comparable to a base of the existing material;
a plurality of pigment oxides for refining the base mixture into a refined pigmented cementitious mixture having color attributes which substantially match the color attributes of the user-selected color;
a plurality of implements including:
a plurality of applying and removing means for applying and removing the mixtures;
a plurality of containing means for containing either the materials, mixtures or both;
a plurality of measuring means for measuring the materials; and
a plurality of accessories.

34. A kit for repair, maintenance and substantial color-match of an existing cementitious material including:
a plurality of materials including:
a plurality of cementitious powders for preparing a base cementitious mixture comparable to a base of the existing material either for substantially matching a user-selected color of or for repairing the existing material;
a plurality of pigment oxides for refining the base mixture into a refined pigmented cementitious mixture having color attributes which substantially match the color attributes of the user-selected color;
a quick-setting mortar repair caulk for repairing large cracks in the existing material;
a urethane sealant for repairing voids in the existing material;
a catalyzed cementitious powder for preparing a catalyzed cementitious mixture for repairing voids in the existing material;
a plurality of implements including:
a plurality of applying and removing means for applying and removing either the materials, mixtures or both;
a plurality of containing means for containing either the materials, mixtures or both;
a plurality of measuring means for measuring the materials; and
a plurality of accessories.

35. The kit of claim 33 or 34 wherein the plurality of applying and removing means include:
a trowel;
a wire brush;
an exploded nylon brush;
a nylon brush;
a plurality of sprayers;
a compressor;
an air gun;
a whisk;
a paint brush; and
a rag.

36. The kit of claim 33 or 34 wherein the plurality of containing means include:
a plurality of resealable containers;
a plurality of buckets; and
a plurality of bottles.

37. The kit of claim 33 or 34 wherein the plurality of measuring means include:
a strainer funnel;
a plurality of measuring spoons;
a plurality of scales; and
a scoop.

38. The kit of claim 33 or 34 wherein the plurality of accessories include:
gloves;
a spray shield;
a plurality of tarps;
a color chart;
a writing utensil; and
paper.

39. The kit of claim 33 or 34 wherein the existing material is stucco.
